(19) United States
(12) Patent Application Publication
(10) Pub. No.: US 2008/0026720 A1
(43) Pub. Date: Jan. 31, 2008

(54) Radio assembly with built-in MP3 player

(76) Inventor: Ghassan Marji, Yonkers, NY (US)

Correspondence Address: James W. Badie, Esq.;Stoll, Miskin & Badie, The Empire State Building, 350 Fifth Avenue, Suite 4710, New York, NY, 10118, US

(21) Appl. No.: 11/495,285

(22) Filed: Jul. 31, 2006

(51) Int. Cl. H05K 11/00; H04B 1/06

(52) U.S. Cl. 455/344

(57) ABSTRACT

A radio assembly is provided with a built-in MP3 player, at least one speaker, a Universal Serial Bus (USB) and a slot, a Secure Digital (SD) card operatively connected to the USB and the MP3 player, and a memory card downloaded with music such that when the memory card is inserted into the SD slot, the downloaded music can be heard through the speakers.

### FIELD OF THE INVENTION

This invention relates generally to a novel and improved radio assembly, and is particularly related to a radio assembly having an MP3 player built in the radio adapted for transfer of music from a music memory card to the MP3 player. More specifically, the present invention relates to such radio-MP3 player combination designed to receive music from a musical memory card which is capable of retaining approximately 30 gigabytes hard drive, and thus can transfer nearly 5,000 songs to the MP3 player to be heard from the radio.

### BACKGROUND OF THE INVENTION

MP3 playback devises are currently prevalent in the market and have been described in several patents and publications. For example, Publication No. US 2001/0044664 A1 published on Nov. 22, 2001, describes a device for playing back multimedia data file from a storage device in an automotive sound system. Another publication, i.e., Publication No. US 2003/0114133 A1, dated Jun. 19, 2003, describes a portable MP3 music player suited for use in vehicles and as a portable personal music player that is carried by the user. The device comprises a housing, one or more memory devices in the housing for storing downloaded music files, communication interface complete with the memory device which interfaces with a computer used to download music files to the portable music player. A microprocessor is coupled to the memory device for controlling the music player, and an audio interface in the housing is coupled to the memory device and the vehicle radio to permit the music file to be heard through the vehicle audio system.

More recently, an audio player assembly comprising MP3 player has been described in Publication No. US 2004/0162029 A1. This system comprises a modular docking unit for docking the MP3 player which comprises a main body with a docking cavity for positioning the MP3 player and coupling means for connecting with an audio output port of the MP3 player to produce audio signals produced by the MP3 . The audio signals are transmitted to an amplifier and the amplified signal is broadcasted by one or more speakers of the radio.

The present invention provides a more efficient and compact radio assembly with the built-in MP3 player which constitutes an improvement over the devices heretofore used in the art.

It is therefore an object of the present invention to provide a radio assembly with a built-in MP3 player which is capable of playing downloaded music.

It is a further object of the present invention to provide such radio assembly which is portable or which can be used in a vehicle.

It is also an object of the present invention to provide a radio assembly with a built-in MP3 player which can be downloaded from a musical memory card capable of retaining approximately 30 gigabytes hard drive to transfer nearly 5,000 songs, audible through one or more radio speakers.

The foregoing and other unique and desired features of the present invention will be appreciated from the ensuing detailed description and the accompanying drawings of the invention.

### SUMMARY OF THE INVENTION

The present invention provides a radio assembly having an integrated MP3 player incorporated in the radio housing and may be used as a portable radio or in a vehicle. The radio assembly itself is defined by a front panel, a rear panel and two side panels which, together, define the housing. An MP3 player is incorporated in the housing and communicates with at least one, preferably two speakers located in the front panel of the radio housing. The speakers are connected to an external headset for hearing the music from the MP3 in the radio.

Two slots are located in the front panel of the radio; one a Secure Digital (SD) slot and the other a Universal Serial Bus (USB) slot. A memory card is downloaded with the music of choice from an external computer. The card can hold as may as 30 gigabytes of hard drive and thus is capable of transferring nearly 5,000 songs to the MP3 player and thus from the MP3 player to the radio speakers. The songs are transferred to the MP3 player by inserting the memory card through the SD slot card.

The radio assembly is also provided with a flip screen for viewing by the person using the radio.

### BRIEF DESCRIPTION OF THE DRAWINGS

In the drawings wherein like reference numerals designate like parts:

FIG. 1 is a front elevational, partly perspective view of the radio assembly of the present invention with a built-in MP3 player and a flip screen in flat horizontal position;

FIG. 2 is a front schematic view of the radio assembly shown in FIG. 1;

FIG. 3 is a view similar to FIG. 1 showing the flip screen partly biased to an inclined raised position; and

FIG. 4 is a schematic view similar to FIG. 2 with the flip screen in full upright position.

### DETAILED DESCRIPTION OF THE INVENTION

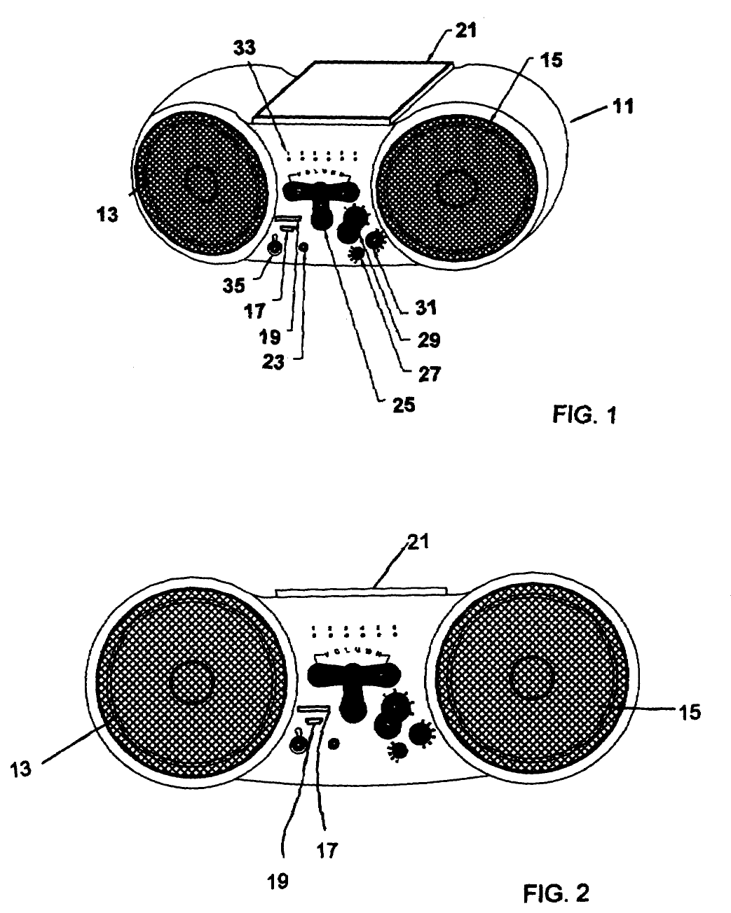

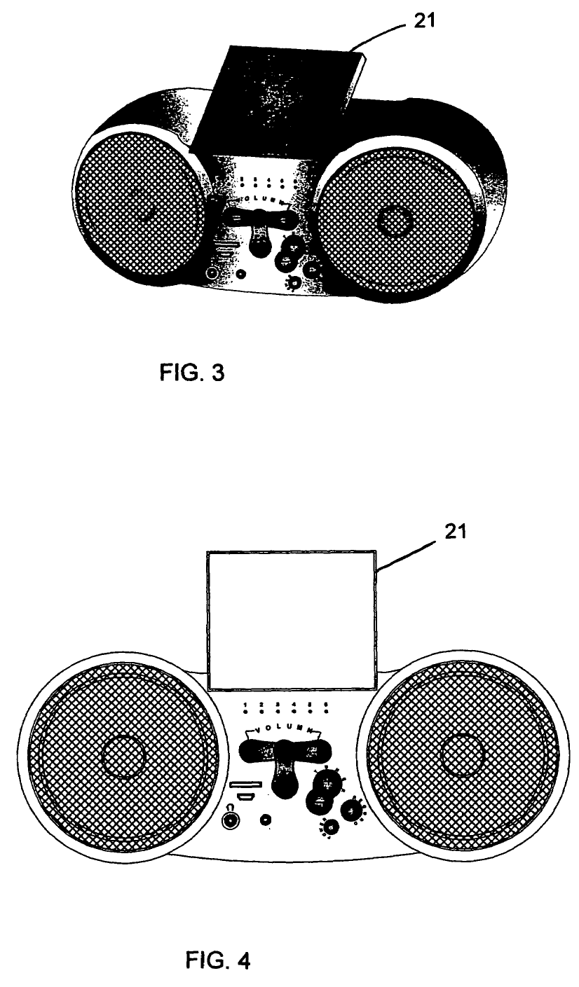

Referring first to FIGS. 1 and 3, there is shown a radio assembly generally designated as 11 which may be a portable radio having two speakers 13 and 15 each equipped with a built-in subwoofer. Located in the lower left side of the radio assembly is slot 17 for a USB (Universal Serial Bus), which enables the user to transfer music from a computer to the radio. Above the USB 17, there is a SD (Secure Digital) card slot 19 for insertion of a memory card to be used in the MP3 player (not shown) which is disposed within the radio.

The USB is a plug and play interface between the computer and add-on devices such as audio players, keyboards, scanners and printers. It is a wire or cable with two attachment ends, one connected to the radio and the other to the computer. Recently, USB drivers have been integrated into Windows operating system. The SD card is a tiny memory card about the size of a postage stamp, and weights approximately 2 grams, and uses metal connector contacts. Both USB and SD have recently been in use, although not in a radio assembly as in the present invention.

The radio assembly is equipped with a flip screen 21 and a flip screen activator 23 which is operatively associated with the flip screen 21 to raise the flip screen to a tilted position as in FIG. 3 or to a fully upright position as shown in FIG. 4. The flip screen is hinged and can be operated manually to assume different positions for convenience of the viewer. The radio assembly 11 is also provided with a scroll 25, power button 27, tuner button 29, record button 31, a radio memory button 33 and an ear phone jack 35 for coupling with connectors (not shown) for hearing music by communication with the user's ears by externally located headset.

The memory card to be used in the MP3 player of the radio assembly is downloaded from an external computer with the music of choice, and as many as 5,000 songs may be downloaded on, and retained by the memory card which can be transferred to the MP3 player by inserting the card through the SD card slot 19.

As previously mentioned, the radio assembly is provided with a flip screen 21 which functions like an MP3 player

The MP3 player which is incorporated integrally into the radio assembly is of the type generally described in the prior art patents and publications hereinbefore described. The MP3 player is connected to radio speakers 13 and 15 by ordinary electrical connection means (not shown).

The radio assembly 11 may be a portable radio or it may be a radio designed for use in a vehicle. In either case, the MP3 player is incorporated in the radio without a loading dock, and in either case music is downloaded from a computer to a memory card which is then inserted through the SD card slot to transfer the music from the memory card to the MP3 player. The downloaded and transferred music can be heard without interference from the radio and viewed from the flip screen.

MP3 players per se are generally known in the prior art and their uses, advantages and disadvantages are described in the aforementioned Publication No. US 2004/0162029 A1 and U.S. Pat. No. 6,591,085 issued Jul. 8, 2003 referred to in said publication.

The uses of memory cards for storing or downloading music from a computer to the music card file is also described in the prior art, such as in the aforementioned Publication No. US 2003/0114133 A1. The music downloaded into the music memory card is, according to the present invention, transferred to the MP3 player through the SD card.

Thus, not only previously downloaded music can be replayed through a vehicle radio but may be replayed and heard from a portable radio. Other variations of the present invention may suggest themselves from the detailed description herein, and are therefore within the contemplation of the invention.

1. A radio assembly comprising:
(a) a housing defined as a front panel, a rear panel and two side panels,
(b) at least one speaker in said housing,
(c) a first slot in said front panel for a Universal Serial Bus (USB),
(d) a second slot in said front panel for a Secure Digital (SD) card,
(e) MP3 player integrally incorporated in said housing operatively connected to said USB and SD, and
(f) a memory card downloaded with music from a computer such that when said memory card is inserted through said second slot, said downloaded music is heard through said speaker.

2. A radio assembly as in claim 1 further including a normally flat flip screen and means operatively associated with said flip screen for adjusting the position between a flat position and a fully upright position.

3. A radio assembly as in claim 1 further including a headset communicating with said ear phone jack in said front panel of said housing.

4. A radio assembly as in claim 2 further including a headset communicating with said ear phone jack in said front panel of said housing.
